(19) United States
(12) Patent Application Publication
(10) Pub. No.: US 2013/0081856 A1
(43) Pub. Date: Apr. 4, 2013

(54) TOUCH PANEL

(71) Applicant: Tse-Kun Chang, Dongshan Township (TW)

(72) Inventor: Tse-Kun Chang, Dongshan Township (TW)

(21) Appl. No.: 13/443,656

(22) Filed: Apr. 10, 2012

(30) Foreign Application Priority Data
Sep. 29, 2011 (TW) 100218271

(51) Int. Cl. H05K 1/02

(52) U.S. Cl. 174/250

(57) ABSTRACT

A touch panel is disclosed, which includes a transparent substrate, a decorative layer, a first conductive layer, a second conductive layer and an isolation layer. The decorative layer is formed on a portion of a surface of the transparent substrate, and the other portion of the surface of the transparent substrate and the decorative layer is coated with the first conductive layer. The isolation layer is disposed between the first and second conductive layers.

### RELATED APPLICATIONS

This application claims priority to Taiwan Application Serial Number 100218271, filed Sep. 29, 2011, which is herein incorporated by reference.

### BACKGROUND

1. Technical Field

The present disclosure relates to panel, and more particularly, touch panels.

2. Description of Related Art

Touch panels are widely used in existing devices, such as automatic teller machines, point of sale terminals, industrial control systems. Because this interface is easy to use, durable, and is not expensive, the market has experienced continued rapid growth.

Referring to FIG. 1, illustrated is a cross-sectional view of a projected capacitive touch panel 100 manufactured by conventional process. In this process, a glass substrate 110 having a decorative membrane 120 is provided and then is attached to two indium tin oxide films by using optical cement 140 and 142. However, aforesaid manufacturing processes are complex, and production costs are increased due to problems in raw material and poor yield.

In view of the foregoing, there is an urgent need in the related field to provide a way to simplify the process and increase yield efficiently.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In one or more various aspects, the present disclosure is directed to novel structure of touch panels for simplifying the process and raw material, and further for increasing yield efficiently.

According to one embodiment of the present invention, a touch panel is disclosed, which includes a transparent substrate, a decorative layer, a first conductive layer, a second conductive layer and an isolation layer. The decorative layer is formed on a portion of a surface of the transparent substrate, and the other portion of the surface of the transparent substrate and the decorative layer are coated with the first conductive layer. The isolation layer is disposed between the first and second conductive layers.

The isolation layer includes a resin layer and a guard resin layer. A surface of the first conductive layer is coated with the resin layer. The guard resin layer is formed on the surface of the first conductive layer and is positioned along the circumference of the resin layer.

The resin layer and the guard resin layer are coated with the second conductive layer.

The touch panel further includes a first conductive ink pattern. The first conductive ink pattern is printed on a portion of a surface of the first conductive layer and is positioned between the first conductive layer and the isolation layer.

The touch panel further includes a second conductive ink pattern. The second conductive ink pattern is printed on a portion of a surface of the second conductive layer and is positioned between the second conductive layer and the isolation layer.

The transparent substrate is a single glass substrate.

The first conductive layer is a first transparent conductive layer.

The first transparent conductive layer is a first indium tin oxide layer.

The second conductive layer is a second transparent conductive layer.

The second transparent conductive layer is a second indium tin oxide layer.

Technical advantages are generally achieved, by embodiments of the present invention, as follows:

(1) The transparent substrate and the decorative layer are directly coated with the first conductive layer without using optical cement, so as to reduce raw material costs and the thickness of the touch panel, and thus, the touch panel can be easily inserted into a thin-type product; and

(2) The isolation layer is disposed between the first and second conductive layers for achieving good isolation effect and thereby enhancing the accuracy of touch panel.

Many of the attendant features will be more readily appreciated, as the same becomes better understood by reference to the following detailed description considered in connection with the accompanying drawings.

### BRIEF DESCRIPTION OF THE DRAWINGS

The present description will be better understood from the following detailed description read in light of the accompanying drawing, wherein:

FIG. 1 is a cross-sectional view of a conventional touch panel; and

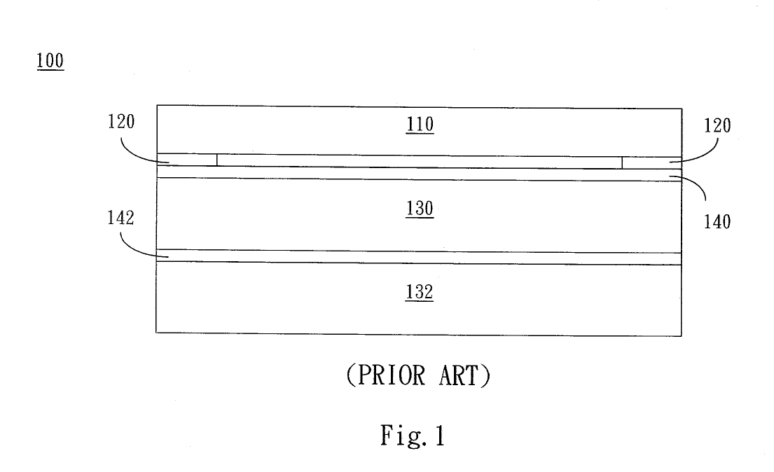

FIG. 2 is a cross-sectional view of a novel touch panel according to one embodiment of the present disclosure.

### DETAILED DESCRIPTION

In the following detailed description, for purposes of explanation, numerous specific details are set forth in order to attain a thorough understanding of the disclosed embodiments. It will be apparent, however, that one or more embodiments may be practiced without these specific details. In other instances, well-known structures and devices are schematically shown in order to simplify the drawing.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

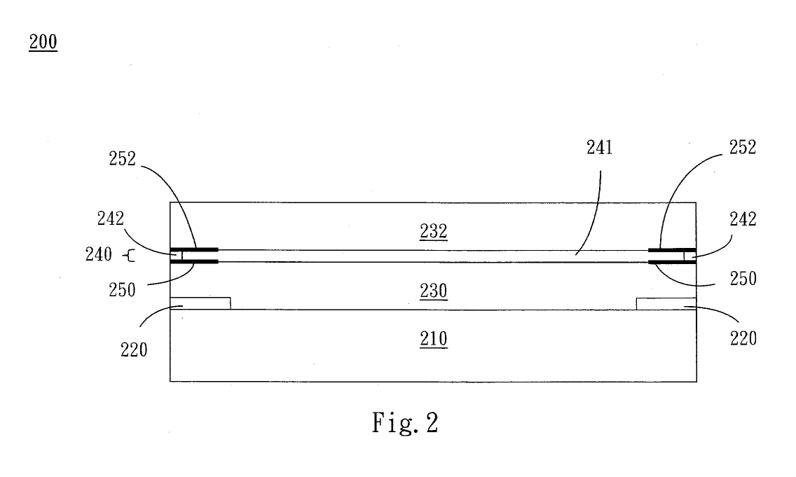

Referring to FIG. 2, illustrated is a cross-sectional view of a touch panel 200 according to one embodiment of the present disclosure. In FIG. 2, the touch panel 200 includes a transparent substrate 210, a decorative layer 220, a first conductive layer 230, a second conductive layer 232 and an isolation layer 240.

As to concrete configuration of the touch panel 200, the decorative layer 220 is formed on a portion of a surface of the transparent substrate 210, and the other portion of the surface of the transparent substrate 210 and the decorative layer 220 is coated with the first conductive layer 230. The isolation layer 240 is disposed between the first conductive layer 230 and the second conductive layer 232.

In this way, the transparent substrate 210 and the decorative layer 220 are directly coated with the first conductive layer 230 without using optical cement, so as to reduce raw material costs and the thickness of the touch panel 200, and thus, the touch panel 220 can be easily inserted into a thin-type product.

The material of the transparent substrate 210 is, for example, an inorganic transparent material (e.g. glass, quartz, other suitable materials, or a combination of the above), an organic transparent material (e.g. polyolefne, polythiourea, polyalcohols, polyester, rubber, a thermoplastic polymer, a thermosetting polymer, polyarylene, polymethylmethacrylate, plastic, polycarbonate, other suitable materials, derivatives of the above, or a combination of the above), or a combination of the above. In this embodiment, the transparent substrate 210 is a single glass substrate.

The first conductive layer 230 can be a first transparent conductive layer. In manufacturing processes, a transparent conductive material (not shown), which is formed of indium tin oxide (ITO), indium zinc oxide (IZO), indium tin zinc oxide (ITZO), hafnium oxide, zinc oxide, aluminum oxide, aluminum tin oxide (ATO), aluminum zinc oxide (AZO), cadmium tin oxide (CTO), cadmium zinc oxide (CZO), other suitable materials, or a combination of the above, is formed on the transparent substrate 210 first, for example. Then, a proper fabricating process is performed to pattern the transparent conductive material, so as to form the first transparent conductive layer. In this embodiment, the first transparent conductive layer is a first indium tin oxide layer.

As shown in FIG. 2, the isolation layer 240 includes a resin layer 241 and a guard resin layer 242. A surface of the first conductive layer 230 is coated with the resin layer 241. The guard resin layer 242 is formed on the surface of the first conductive layer 230 and is positioned along the circumference of the resin layer 241.

In practice, the resin layer 241 and the guard resin layer 242 are coated with the second conductive layer 230. In this way, the isolation layer 240 is directly coated with the second conductive layer 230 without using additional and optical cement, so as to reduce raw material costs and the thickness of the touch panel 200, and thus, the touch panel 220 can be easily inserted into a thin-type product.

The second conductive layer 232 can be a second transparent conductive layer. In manufacturing processes, a transparent conductive material (not shown), which is formed of indium tin oxide (ITO), indium zinc oxide (IZO), indium tin zinc oxide (ITZO), hafnium oxide, zinc oxide, aluminum oxide, aluminum tin oxide (ATO), aluminum zinc oxide (AZO), cadmium tin oxide (CTO), cadmium zinc oxide (CZO), other suitable materials, or a combination of the above, is formed on the isolation layer 240 first, for example. Then, a proper fabricating process is performed to pattern the transparent conductive material, so as to form the second transparent conductive layer. In this embodiment, the second transparent conductive layer is a second indium tin oxide layer.

As shown in FIG. 2, the touch panel 200 may includes a first conductive ink pattern 250. The first conductive ink pattern 250 is printed on a portion of a surface of the first conductive layer 230 and is positioned between the first conductive layer 230 and the isolation layer 240. The material of the first conductive ink pattern 250 is, for example, carbon paste, silver paste, other suitable materials, or a combination of the above.

Moreover, the touch panel 200 may also includes a second conductive ink pattern 252. The second conductive ink pattern 252 is printed on a portion of a surface of the second conductive layer 232 and is positioned between the second conductive layer 232 and the isolation layer 240. The material of the second conductive ink pattern 252 is, for example, carbon paste, silver paste, other suitable materials, or a combination of the above.

In use, the first conductive ink pattern 250 can transmit electric signal for the first conductive layer 230 because the first conductive ink pattern 250 is electrically connected to the first conductive layer 230. Similarly, the second conductive ink pattern 252 can transmit electric signal for the second conductive layer 232 because the second conductive ink pattern 252 is electrically connected to the second conductive layer 232.

Furthermore, the decorative layer 220 is positioned around the margin of one surface of the transparent substrate 210. In use, the decorative layer 220 can mask the conductive ink patterns and render its decorative patterns.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims herein is not intended to invoke the provisions of 35 U.S.C. §112, 6th paragraph.

What is claimed is:

1. A touch panel comprising:
a transparent substrate;
a first conductive layer;
a decorative layer formed on a portion of a surface of the transparent substrate, wherein the other portion of the surface of the transparent substrate and the decorative layer are coated with the first conductive layer;
a second conductive layer; and
an isolation layer disposed between the first and second conductive layers.

2. The touch panel of claim 1, wherein the isolation layer comprises:
a resin layer, wherein a surface of the first conductive layer is coated with the resin layer; and
a guard resin layer formed on the surface of the first conductive layer and positioned along the circumference of the resin layer.

3. The touch panel of claim 2, wherein the resin layer and the guard resin layer are coated with the second conductive layer.

4. The touch panel of claim 1, further comprising:
a first conductive ink pattern printed on a portion of a surface of the first conductive layer and positioned between the first conductive layer and the isolation layer.

5. The touch panel of claim 4, further comprising:
a second conductive ink pattern printed on a portion of a surface of the second conductive layer and positioned between the second conductive layer and the isolation layer.

6. The touch panel of claim 1, wherein the transparent substrate is a single glass substrate.

7. The touch panel of claim 1, wherein the first conductive layer is a first transparent conductive layer.

8. The touch panel of claim 7, wherein the first transparent conductive layer is a first indium tin oxide layer.

9. The touch panel of claim 8, wherein the second conductive layer is a second transparent conductive layer.

10. The touch panel of claim 9, wherein the second transparent conductive layer is a second indium tin oxide layer.
